(19) United States
(12) Patent Application Publication
(10) Pub. No.: US 2007/0080413 A1
(43) Pub. Date: Apr. 12, 2007

(54) CMOS image sensor and method for manufacturing the same

(76) Inventor: Sung Ho Kwak, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/580,176

(22) Filed: Oct. 11, 2006

(30) Foreign Application Priority Data
Oct. 12, 2005 (KR) 10-2005-0095899

(51) Int. Cl. H01L 27/14

(52) U.S. Cl. 257/431

(57) ABSTRACT

A CMOS image sensor is provided. The CMOS image sensor incorporates a semiconductor substrate having a photodiode area and a transistor area; a trench area formed in the photodiode area; a transistor and a floating diffusion area formed on the transistor area; a first conductive type diffusion area formed on the photodiode area; and a second conductive type diffusion area formed on the trench area above the first conductive diffusion area.

### RELATED APPLICATION

This application claims the benefit under 35 U.S.C. §119(e), of Korean Patent Application Number 10-2005-0095899 filed Oct. 12, 2005, which is incorporated herein by reference in its entirety.

### FIELD OF THE INVENTION

The present invention relates to a complementary metal oxide semiconductor (CMOS) image sensor.

### BACKGROUND OF THE INVENTION

In general, an image sensor is a semiconductor device for converting optical images into electric signals, and is typically classified as a charge coupled device (CCD) or a CMOS image sensor.

The CCD has a plurality of photodiodes (PDs), which are arranged in the form of a matrix in order to convert optical signals into electric signals. The CCD includes a plurality of vertical charge coupled devices (VCCDs) provided between photodiodes and vertically arranged in the matrix so as to transmit electrical charges in the vertical direction when the electrical charges are generated from each photodiode; a plurality of horizontal charge coupled devices (HCCDs) for transmitting in the horizontal direction the electrical charges that have been transmitted from the VCCDs; and a sense amplifier for outputting electric signals by sensing the electrical charges being transmitted in the horizontal direction.

However, such a CCD has various disadvantages, such as a complicated drive mode, high power consumption, and so forth. Also, the CDD requires multi-step photolithography processes, so the manufacturing process for the CCD is complicated.

In addition, since it is difficult to integrate a controller, a signal processor, and an analog/digital converter (A/D converter) onto a single chip of the CCD, the CCD is not suitable for compact-size products.

Recently, the CMOS image sensor has been spotlighted as the next-generation image sensor capable of solving problems of the CCD.

The CMOS image sensor is a device that employs a switching mode to sequentially detect an output of each unit pixel by means of MOS transistors using peripheral devices, such as a controller and a signal processor. The MOS transistors are formed on a semiconductor substrate corresponding to the unit pixels through a CMOS technology.

That is, the CMOS sensor includes a photodiode and a MOS transistor in each unit pixel, and sequentially detects the electric signals of each unit pixel in a switching mode to realize images.

Since the CMOS image sensor makes use of the CMOS technology, the CMOS image sensor has advantages such as low power consumption and a simple manufacturing process with a relatively smaller number of photolithography processing steps.

In addition, the CMOS image sensor allows the product to have a compact size, because the controller, the signal processor, and the A/D converter can be integrated onto a single chip of the CMOS image sensor.

Therefore, CMOS image sensors have been extensively used in various applications, such as digital still cameras, digital video cameras, and so forth.

Meanwhile, in the conventional CMOS image sensor, the saturation level of the unit pixel is determined according to the capacitance ratio between the photodiode and a floating diffusion area. In order to improve the saturation level, capacitance of the photodiode must be higher than that of the floating diffusion area.

However, since the capacitance of the floating diffusion area may exert an influence upon characteristics of various transistors, it can be undesirable to change the capacitance of the floating diffusion area.

Accordingly, it is necessary to increase the capacitance of the photodiode. However, since the chip size must be enlarged to increase the capacitance of the photodiode, there are limitations to improve the saturation level of the unit pixel.

### SUMMARY OF THE INVENTION

An object of the present invention is to provide a CMOS image sensor and a method for manufacturing the same, capable of improving the saturation level of a unit pixel by enlarging a surface area of a depletion layer formed in a photodiode such that capacitance of the photodiode can be increased.

According to one aspect of the present invention, there is provided a CMOS image sensor comprising: a semiconductor substrate having a photodiode area and a transistor area; a trench area formed in the photodiode area; a transistor and a floating diffusion region formed on the transistor area; a first conductive type diffusion region formed on the photodiode area; and a second conductive type diffusion region formed on the trench area above the first conductive type diffusion region.

According to another aspect of the present invention, there is provided a CMOS image sensor comprising: a semiconductor substrate having an active area and an isolation area; a photodiode area and a floating diffusion region formed in the active area; a transfer transistor for transferring photo-charges from the photodiode area to the floating diffusion region; and a plurality of trenches formed on a surface of the photodiode area

According to still another embodiment of the present invention, there is provided a method for forming a CMOS image sensor, the method comprising: defining a photodiode area on an active area of a semiconductor substrate and forming a plurality of trenches in the photodiode area; forming a gate insulating layer and a gate electrode on the active area; forming a first conductive type diffusion region by implanting a dopant into the photodiode area; forming a spacer at a side of the gate electrode; forming a first conductive type floating diffusion region by implanting a dopant into the active area; and forming a second conductive type diffusion region by implanting a dopant into the photodiode area.

### BRIEF DESCRIPTION OF THE DRAWINGS

The accompanying drawings, which are included to provide a further understanding of the invention and are incorporated in and constitute a part of this application, illustrate embodiment(s) of the invention together with the description, and serve to explain the principle of the invention.

FIG. 1 is a circuit view illustrating a unit pixel of a CMOS image sensor including four transistors and two capacitors according to an exemplary embodiment of the present invention;

FIG. 2 is a layout view illustrating a unit pixel of a CMOS image sensor according to an exemplary embodiment of the present invention;

FIG. 3 is a sectional view taken along line A-A of FIG. 2 to illustrate a photodiode part of a unit pixel and a transfer transistor according to an embodiment of the subject invention; and

FIGS. 4A to 4G are sectional views illustrating the procedure for manufacturing a CMOS image sensor according to an exemplary embodiment of the present invention.

### DETAILED DESCRIPTION OF THE PREFERRED EMBODIMENTS

Hereinafter, a preferred embodiment of the present invention will be described with reference to the accompanying drawings.

CMOS image sensors are typically classified as 3T, 4T or 5T-type CMOS image sensors according to the number of transistors formed in a unit pixel. The 3T-type CMOS image sensor includes one photodiode and three transistors, and the 4T-type CMOS image sensor includes one photodiode and four transistors.

In the following description of the present invention, the 4T-type CMOS image sensor will be used as an example to explain the CMOS image sensor and the manufacturing method thereof. The layout for the unit pixel of the 4T-type CMOS image sensor is as follows:

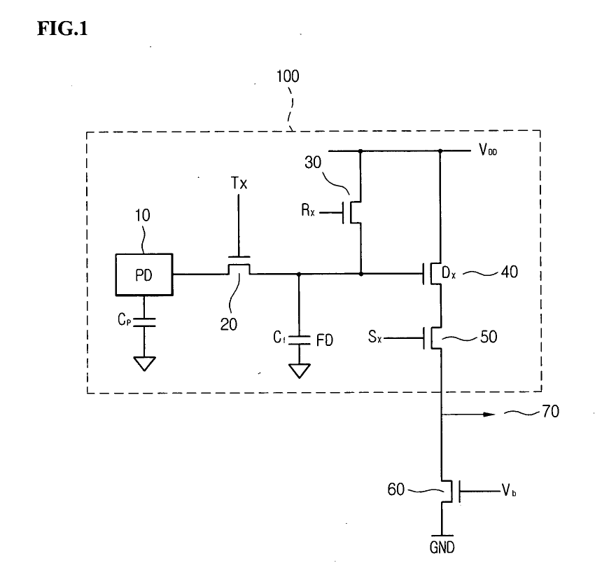

FIG. 1 is a circuit view illustrating a unit pixel 100 of a CMOS image sensor including four transistors and two capacitors according to an exemplary embodiment of the present invention.

FIG. 1 shows the unit pixel 100 of the CMOS image sensor including a photodiode PD 10 for detecting light and four NMOS transistors. The four NMOS transistors include a transfer transistor 20, a reset transistor 30, a drive transistor 40 and a select transistor 50.

As shown in FIG. 1, from among the four NMOS transistors, the transfer transistor 20 transfers a signal to transmit photo-charges generated from the photodiode 10 to a floating diffusion region FD, the reset transistor 30 transfers a signal to reset the floating diffusion region to a level of a supply voltage V_{DD}, the drive transistor 40 serves as a source follower, and the select transistor 50 receives a pixel data enable signal so as to transmit a pixel data signal.

A load transistor 60 can be electrically connected to an output terminal 70 of the unit pixel 100. In FIG. 1, Tx refers to a gate voltage of the transfer transistor 20, Rx refers to a gate voltage of the reset transistor 30, Dx refers to a gate voltage of the drive transistor 40, and Sx refers to a gate voltage of the select transistor 50.

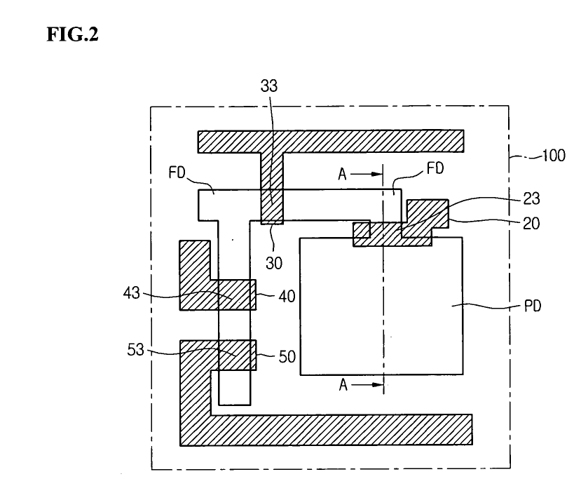

FIG. 2 is a layout view illustrating the unit pixel of the CMOS image sensor according to an exemplary embodiment of the present invention.

As shown in FIG. 2, the unit pixel 100 includes an active area, which is shown in a solid line, and an isolation area having an isolation layer and being formed at an outside of the active layer.

A gate 23 of the transfer transistor 20, a gate 33 of the reset transistor 30, a gate 43 of the drive transistor 40, and a gate 53 of the select transistor 50 can be aligned above the active area while crossing the active area.

Referring to FIGS. 1 and 2, the unit pixel 100 of the CMOS image sensor having the above structure operates as follows:

First, the reset transistor 30, the transfer transistor 20, and the select transistor 50 can be turned on, thereby resetting the unit pixel 100.

At this time, depletion of the photodiode 10 occurs, so that carrier charge is generated. The floating diffusion region FD is charged with carriers to a level of the supply voltage V_{DD}.

Then, the transfer transistor 20 can be turned off, and the select transistor 50 can be turned on. After that, the reset transistor 30 can be turned off.

In this state, a controller can read the output voltage V1 from the output terminal 70 of the unit pixel 100 and can store the output voltage V1 in a buffer. Then, the controller can turn on the transfer transistor 20 so as to shift carriers of a capacitor Cp, which is charged according to intensity of light, into a capacitor Cf After that, the controller reads out the output voltage V2 from the output terminal 70 of the unit pixel 100 and can convert analog data for the output voltages V1 and V2 into digital data, thereby completing one operational period of the unit pixel 100.

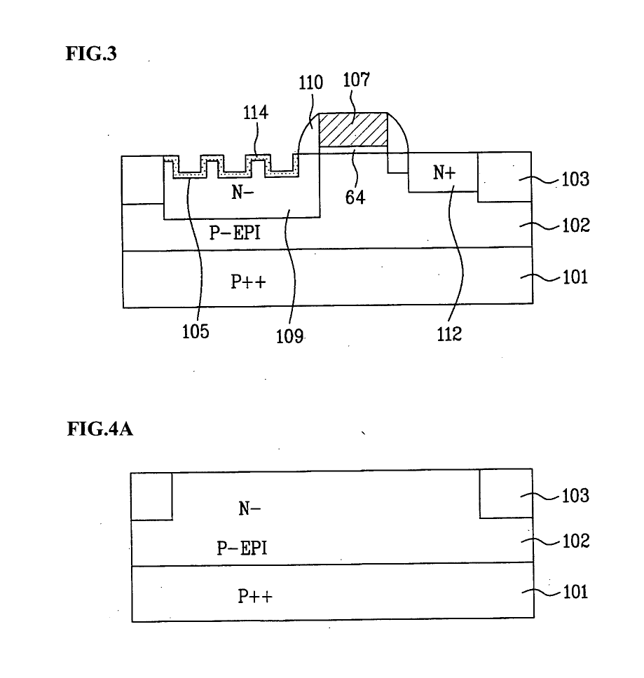

FIG. 3 is a sectional view taken along line A-A of FIG. 2 to illustrate an embodiment of a photodiode part of the unit pixel and the transfer transistor.

As shown in FIG. 3, the CMOS image sensor according to an embodiment of the present invention can include a p type epitaxial layer 102 formed on a p⁺⁺ type conductive semiconductor substrate 101, on which an active area having a photodiode area and a transistor area, and an isolation area are defined. An isolation layer 103 can be formed on the isolation area in order to define the active area of the semiconductor substrate 101. A plurality of trenches 105 can be formed having a predetermined depth while being spaced apart from each other by a predetermined interval in the photodiode area of the semiconductor substrate 101. A gate electrode 107 can be formed on the active area of the semiconductor substrate 101 by interposing a gate insulating layer 106 therebetween. A low-density n⁻ type diffusion region 109 can be formed on the photodiode area in the vicinity of the gate electrode 107. A spacer 110 can be formed at a side of the gate electrode 107. A high-density n⁺ type diffusion region (floating diffusion region) 112 can be formed on the transistor area at the other side of the gate electrode 107. A p⁰ type diffusion region 114 can be formed on the surface of the trench 105 in the semiconductor substrate 101 on which the low-density n⁻ type diffusion region 109 is formed.

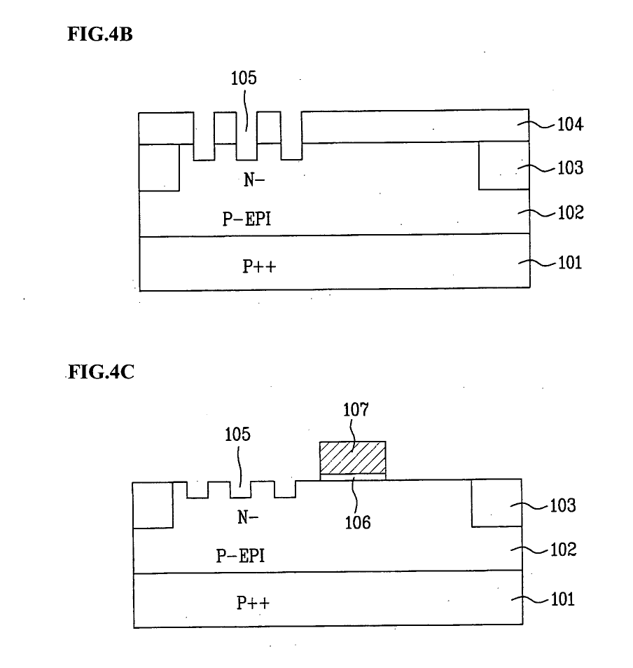

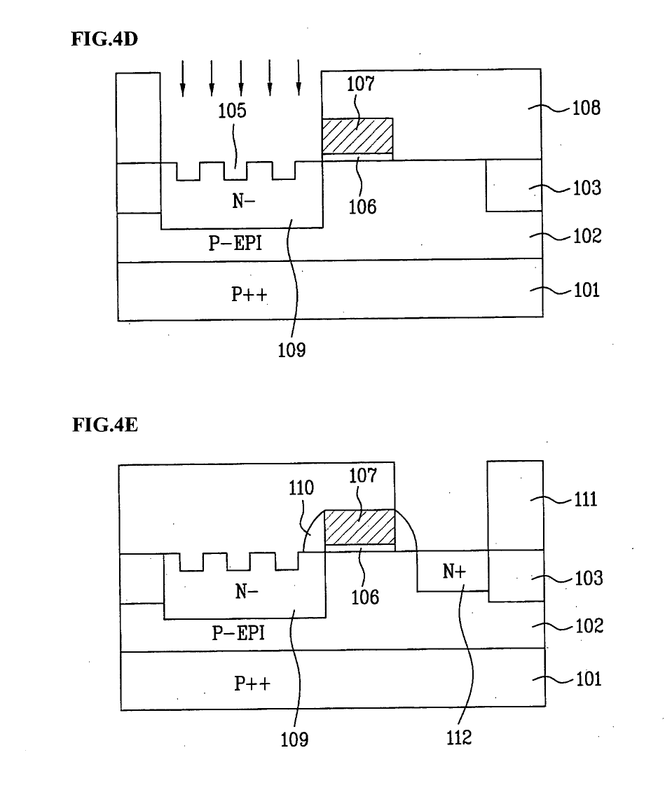

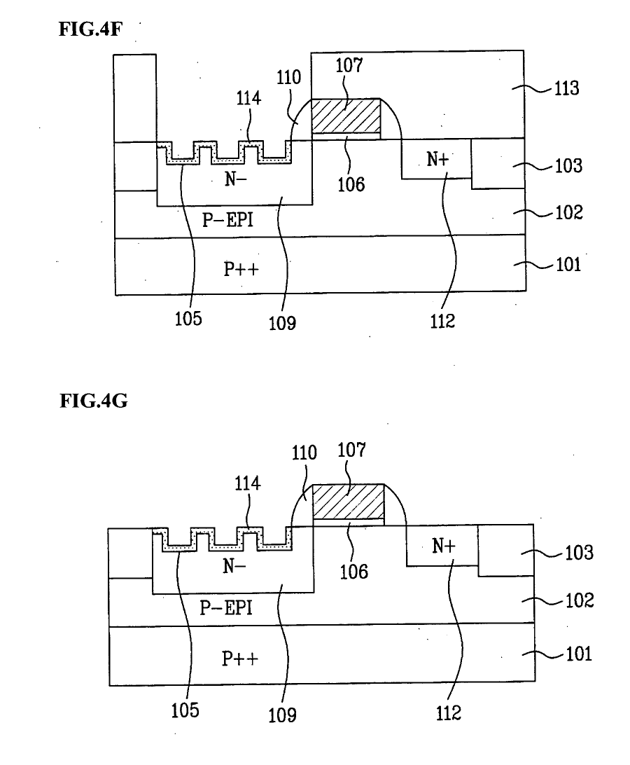

FIGS. 4A to 4G are sectional views illustrating a method for manufacturing the CMOS image sensor according to an exemplary embodiment of the present invention.

As shown in FIG. 4A, a low-density p⁻ type epitaxial layer 102 can be formed on a high-density p⁺⁺ type conductive semiconductor substrate 101 through an epitaxial process.

Then, after defining an active area and an isolation area on the semiconductor substrate 101, the isolation layer 103 can be formed on the isolation area of the semiconductor substrate 101 by, for example, performing an STI (shallow trench isolation) process.

Although it is not illustrated in figures, the isolation layer 103 can be formed as follows:

First, a pad oxide layer, a pad nitride layer, and a TEOS (tetra-ethyl-ortho-silicate) oxide layer can be sequentially formed on the semiconductor substrate. A photoresist film can be coated on the TEOS oxide layer.

Then, an exposure and development process can be performed with respect to the photoresist film by using a mask having a pattern for defining an active area and an isolation area, thereby patterning the photoresist film. Through this photolithography process, the photoresist film formed on the isolation area can be removed, exposing the TEOS oxide layer.

After that, the pad oxide layer, the pad nitride layer and the TEOS oxide layer formed on the isolation area can be selectively removed using the patterned photoresist film as an etch mask.

Then, the isolation area of the semiconductor substrate can be etched to a predetermined depth, thereby forming a trench. The substrate can be etched using the patterned pad oxide layer, pad nitride layer and TEOS oxide layer as an etch mask. After that, the photoresist film can be completely removed.

Then, insulating materials can be filled in the trench, thereby forming the isolation layer 103. After that, the pad oxide layer, the pad nitride layer and the TEOS oxide layer can be removed.

Referring to FIG. 4B, a first photoresist film 104 can be coated on the entire surface of the semiconductor substrate 101 formed with the isolation layer 103. Then, the first photoresist film 104 can be selectively patterned through an exposure and development process to expose a portion of a photodiode area on the semiconductor substrate 101.

Subsequently, the exposed semiconductor substrate 101 can be selectively etched using the patterned first photoresist film 104 as an etch mask to form a plurality of trenches 105 on the photodiode area The trenches 105 can have predetermined depths and can be spaced apart from each other by a predetermined interval.

Then, as shown in FIG. 4C, after removing the first photoresist film 104, a gate insulating layer and a conductive layer (for instance, a high density multi-crystalline silicon layer) can be sequentially deposited on the entire surface of the epitaxial layer 102 formed with the isolation layer 103. In an embodiment, the gate insulating layer 106 can be formed through a thermal oxidation process or a chemical vapor deposition (CVD) process.

The conductive layer and the gate insulating layer 106 can be selectively removed to form a gate electrode 107.

The gate electrode 107 serves as a gate electrode of the transfer transistor.

Referring to FIG. 4D, a second photoresist film 108 can be coated on the entire surface of the semiconductor substrate 101 including the gate electrode 107. The second photoresist film 108 can be patterned through an exposure and development process to expose the photoresist area

Then, a low-density first conductive type (in this case n⁻ type) dopant can be implanted into the epitaxial layer 102 using the patterned second photoresist film 108 as a mask to form n⁻ type diffusion region 109.

Referring to FIG. 4E, an insulating layer can be formed on the entire surface of the semiconductor substrate 101 including the gate electrode 107, and then an etch back process can be performed to form a spacer 110.

Then, a third photoresist film 111 can be coated on the semiconductor substrate 101 including the gate electrode 107. The third photoresist film 111 can be patterned through an exposure and development process to expose a drain area of the transistor.

A high-density first conductive type (in this case n⁺ type) dopant can be implanted into the exposed drain area using the patterned third photoresist film 111 as a mask to form n⁺ type diffusion region 112 (floating diffusion region).

Then, as shown in FIG. 4F, after removing the third photoresist film 111, a fourth photoresist film 113 can be coated on the entire surface of the semiconductor substrate 101. The fourth photoresist film 113 can be patterned through an exposure and development process to expose the photodiode area.

After that, a second conductive type (in this case p⁰ type) dopant can be implanted into the epitaxial layer 102 formed with the n⁻ type diffusion region 109 by using the patterned fourth photoresist film 113 as a mask to form p⁰ type diffusion region 114 on the surface of the epitaxial layer 102 formed with the trench 105.

Then, as shown in FIG. 4G, the fourth photoresist film 113 can be removed and the semiconductor substrate 101 can be subject to a heat-treatment process so as to diffuse each impurity diffusion region.

After that, although not illustrated in figures, a plurality of metal interconnections including interlayer dielectric layers can be formed on the entire surface of the resultant structure, and then a color filter layer and a micro-lens can be formed to form an image sensor.

As described above, the CMOS image sensor and the manufacturing method thereof according to embodiments of the present invention represent following advantages.

That is, according to embodiments of the present invention, a plurality of trenches having a predetermined depth can be formed on the photodiode area through an etching process, and a p⁰ type diffusion region can be formed on the surface of the plurality of trenches, so that a surface area of the depletion layer of the photodiode can be enlarged. Accordingly, capacitance of the photodiode can be increased, so that the saturation level of the unit pixel can be improved.

It will be apparent to those skilled in the art that various modifications and variations can be made in the present invention. Thus, it is intended that the present invention covers the modifications and variations of this invention provided they come within the scope of the appended claims and their equivalents.

I claim:

1. A CMOS image sensor comprising:
a semiconductor substrate having a photodiode area and a transistor area;
a trench area formed in the photodiode area;
a transistor and a floating diffusion region formed on the transistor area;
a first conductive type diffusion region formed on the photodiode area; and
a second conductive type diffusion region formed on the trench area above the first conductive type diffusion region.

2. The CMOS image sensor according to claim 1, wherein a plurality of trenches are formed in the trench area.

3. The CMOS image sensor according to claim 1, wherein the semiconductor substrate comprises a second conductive type semiconductor substrate.

4. The CMOS image sensor according to claim 1, wherein the floating diffusion region comprises a first conductive type floating diffusion region.

5. The CMOS image sensor according to claim 1, wherein the transistor comprises a gate insulating layer, a gate electrode formed on the gate insulating layer, and a spacer formed at a side of the gate electrode.

6. The CMOS image sensor according to claim 1, wherein the first conductive type is n type, and the second conductive type is p type.

7. A CMOS image sensor comprising:
a semiconductor substrate having an active area and an isolation area;
a photodiode area and a floating diffusion region formed in the active area;
a transfer transistor for transferring photo-charges from the photodiode area to the floating diffusion region; and
a plurality of trenches formed on a surface of the photodiode area.

8. The CMOS image sensor according to claim 7, wherein the photodiode area comprises:
a first conductive type diffusion region, and
a second conductive type diffusion region formed in the plurality of trenches at an upper portion of the first conductive diffusion region.

9. The CMOS image sensor according to claim 7, wherein the photodiode area comprises:
a second conductive type diffusion area formed on a surface of the photodiode area, and a first conductive type diffusion area formed at a lower portion of the transfer transistor.

10. The CMOS image sensor according to claim 7, wherein the semiconductor substrate comprises a second conductive type semiconductor substrate.

11. The CMOS image sensor according to claim 7, wherein the floating diffusion region comprises a first conductive type floating diffusion region.

12. The CMOS image sensor according to claim 7, wherein the transfer transistor comprises a gate insulating layer, a gate electrode formed on the gate insulating layer, and a spacer formed at a side of the gate electrode.

13. The CMOS image sensor according to claim 8, wherein the first conductive type is n type, and the second conductive type is p type.

14. A method for forming a CMOS image sensor, comprising:
defining a photodiode area on an active area of a semiconductor substrate and forming a plurality of trenches in the photodiode area;
forming a gate insulating layer and a gate electrode on the active area;
forming a first conductive type diffusion region by implanting a dopant into the photodiode area;
forming a spacer at a side of the gate electrode;
forming a first conductive type floating diffusion region by implanting a dopant into the active area; and
forming a second conductive type diffusion region by implanting a dopant into the photodiode area

15. The method according to claim 14, wherein the photodiode area is formed on a first side of the gate electrode, and the floating diffusion area is formed on a second side of the gate electrode.

16. The method according to claim 14, wherein the first conductive type is n type and the second conductive type is p type.
